(19) United States
(12) Patent Application Publication
(10) Pub. No.: US 2002/0197793 A1
(43) Pub. Date: Dec. 26, 2002

(54) Low thermal budget metal oxide deposition for capacitor structures

(76) Inventors: Charles N Dornfest, Fremont, CA (US); Xiaoliang Jin, San Jose, CA (US); Yaxin Wang, Fremont, CA (US); Jun Zhao, Cupertino, CA (US); Yasutoshi Okuno, Kyoto (JP); Akihiko Tsuzumitani, Ibaraki (JP); Yoshihiro Mori, Kyoto (JP); Shreyas Kher, Campbell, CA (US); Annabel Nickles, Palo Alto, CA (US); Xianzhi (Jerry) Tao, Palo Alto, CA (US)

Correspondence Address: William B Patterson, Moser Patterson & Sheridan, Suite 1500, 3040 Post Oak Blvd, Houston, TX, 77056, US

(21) Appl. No.: 09/936,070

(22) PCT Filed: Jan. 8, 2001
(86) PCT No.: PCT/US01/00554

(51) Int. Cl. H01L 21/8242; H01L 21/31; H01L 21/469

(52) U.S. Cl. 438/253; 438/256; 438/239; 438/240; 438/785

(57) ABSTRACT

In one embodiment, the process comprises depositing a CVD metal oxide layer on the substrate at a substrate temperature of less than or equal to about 480° C. and annealing the metal oxide layer. In one aspect, annealing comprises providing a first substrate temperature between abut 600° C. and 900° C., maintaining the first substrate temperature for a time period of between about 0.1 seconds and 30 minutes, providing a second substrate temperature between about 500° C. to 600° C., and maintaining the second substrate temperature for a time period of at least 10 minutes. In another embodiment, the process comprises depositing a first electrode; depositing a CVD metal oxide layer on the first electrode at a substrate temperature of less than or equal to about 480° C.; and depositing a second electrode on the oxide layer. In one aspect the metal oxide layer is annealed prior to deposition of the second electrode. In another aspect, the metal oxide layer is anneal subsequent to deposition of the second electrode. In one aspect, annealing comprises providing a first substrate temperature between about 600° C. and 900° C., maintaining the first substrate temperature for a time period of between about 0.1 seconds and 30 minutes, providing a second substrate temperature between about 500° C. to 600° C., and maintaining the second substrate temperature for a time period of at least 10 minutes. In another aspect, the present invention provides a capacitor comprising a platinum bottom electrode, a platinum top electrode, and a dielectric layer disposed between in which the capacitor has a current leakage of less than 10 fA/cell.

This application claims priority to Provisional U.S. patent application Ser. No. 60/174,983, filed on Jan. 6, 2000, which is hereby incorporated by reference in its entirety.

### BACKGROUND OF THE INVENTION

1. Field of the Invention

The invention relates to a process for the deposition of a metal-oxide film on a substrate. The invention also relates to a process for the deposition of a metal-oxide film on a conductive material such as the deposition of BST on a platinum electrode to fabricate capacitors used in dynamic random-access memory modules.

2. Background of the Invention

Dynamic random-access memory (DRAM) integrated circuits are commonly used for storing data in a digital computer. Currently available DRAMs may contain over 16 million memory cells fabricated on a single silicon chip, and each memory cell generally comprises a single transistor connected to a micron or sub-micron sized capacitor. In operation, each capacitor may be individually charged or discharged in order to “store” one bit of information. A DRAM is dynamic in the sense that charged memory cells must be refreshed or recharged periodically to maintain data integrity, otherwise, charged memory cells may quickly discharge through leakage. To facilitate construction of 64 Mbit, 256 Mbit, 1 Gbit, and larger DRAMs with correspondingly smaller memory cells, capacitor structures and materials which can store the necessary charge in less chip space are needed.

One of the most promising avenues of research is in the area of high dielectric constant (HDC) materials. Capacitors containing high-dielectric-constant materials in theory have much larger capacitance densities than the standard SiO₂—Si₃N₄—SiO₂ stack capacitors. One high dielectric constant material of increasing interest for use in ultra large scale integrated (ULSI) DRAMs is barium strontium titanate, Ba_{[1-x]}Sr_{[x]}TiO₃ (BST). Deposition techniques used in the past to deposit BST include RF magnetron sputtering, laser ablation, sol-gel processing, and chemical vapor deposition (CVD) of metal organic materials.

However, various problems exist in commercial implementation of HDC materials, such as BST, in capacitor structures. One problem with current capacitor fabrication utilizing BST is the relatively high temperatures required to deposit and anneal the BST layer formed in capacitor structures. For example, the relatively high temperatures may degrade the electrode or the transistor device formed below the capacitor.

Therefore, there is a need for a process of forming an improved HDC dielectric layer without substantially degrading devices already formed on a substrate. Furthermore, there is a need for a method for forming a capacitor structure without substantially degrading an underlying electrode or device.

### SUMMARY OF THE INVENTION

The invention relates generally to a process for depositing a metal-oxide film on a substrate. More particularly, the invention relates to a process for depositing of a metal-oxide film on a conductive material to fabricate a capacitor structure.

In one embodiment, the process comprises depositing a CVD metal oxide layer on the substrate at a substrate temperature of less than or equal to about 480° C. and annealing the metal oxide layer. In one aspect, annealing comprises providing a first substrate temperature between about 600° C. and 900° C., maintaining the first substrate temperature for a time period of between about 0.1 seconds and 30 minutes, providing a second substrate temperature between about 500° C. to 600° C., and maintaining the second substrate temperature for a time period of at least 10 minutes.

In another embodiment, the process comprises depositing a first electrode; depositing a CVD metal oxide layer on the first electrode at a substrate temperature of less than or equal to about 480° C.; and depositing a second electrode on the oxide layer. In one aspect the meal oxide layer is annealed prior to deposition of the second electrode. In another aspect, the metal oxide layer is anneal subsequent to deposition of the second electrode. In one aspect, annealing comprises providing a first substrate temperature between about 600° C. and 900° C., maintaining the first substrate temperature for a time period of between about 0.1 seconds and 30 minutes, providing a second substrate temperature between about 500° C. to 600° C., and maintaining the second substrate temperature for a time period of at least 10 minutes.

In another aspect, the present inventionn provides a capacitor comprising a platinum bottom electrode, a platinum top electrode, and a dielectric layer disposed between in which the capacitor has a current leakage of less than 10 fA/cell.

In another embodiment, the process comprises depositing comprising depositing a CVD metal oxide layer on the substrate at a substrate temperature of less than or equal to about 480° C. and annealing the metal oxide layer. In one aspect, annealing comprises providing a first substrate temperature between about 500° C. and 900° C., maintaining the first substrate temperature for a time period of between about 0.1 seconds and 30 minutes, and providing a second substrate temperature between about 500° C. to 750° C.

### BRIEF DESCRIPTION OF THE FIGURES

FIG. 1 is a cross sectional view of a chamber for depositing a metal oxide layer.

FIG. 2 is a top view of a lid for the chamber of FIG. 1.

FIG. 3 is a schematic of a liquid delivery system.

FIG. 4 is a perspective view of a zero dead volume valve.

FIG. 5 is cross sectional view of a PVD chamber.

FIGS. 6-7 are graphical representations of characteristics of a preferred CVD BST 200 mm process.

FIGS. 8a-f are schematic cross sectional views of one embodiment of fabricating a capacitor having a 3-D cup type structure.

FIG. 9 an electron scanning microscope photograph of a 3-D cup structure cross-section.

FIG. 10 is a graph of the leakage current density of a 3-D capacitor for a 256 k equivalent array.

FIG. 11 is a cross sectional view of another embodiment of a DRAM device having a trench capacitor.

### DETAILED DESCRIPTION OF THE PREFERRED EMBODIMENT

Metal Oxide Deposition Chamber

In one embodiment of the present invention, barium strontium titanate (BST) is used as the dielectric material between the electrodes of a capacitor. Other high dielectric constant (HDC) materials may be used in the present process include, but is not limited to, tantalum pentoxide (Ta₂O₅), zirconate titanate (ZrxTiyOz), strontium titante (SrTiO₃), lead zirconate titanate (PZT), lanthanum-doped PZT, bismuth titanate (Bi₄Ti₃O₁₂), barium titanate (BaTiO₃), or the like.

While the process of the invention can be practical using a wide variety of CVD equipment, the following description provides an example of equipment that can be used to successfully deposit a metal oxide layer on a substrate according to a process of the invention. A detailed description of the equipment briefly described below is provided in issued U.S. Pat. No. 6,056,823, entitled “Temperature Controlled Gas Feedthrough,” which is a divisional application of U.S. patent application Ser. No. 08/927,700 filed Sep. 11, 1997, which is hereby incorporated by reference in its entirety to the extent not inconsistent with the invention.

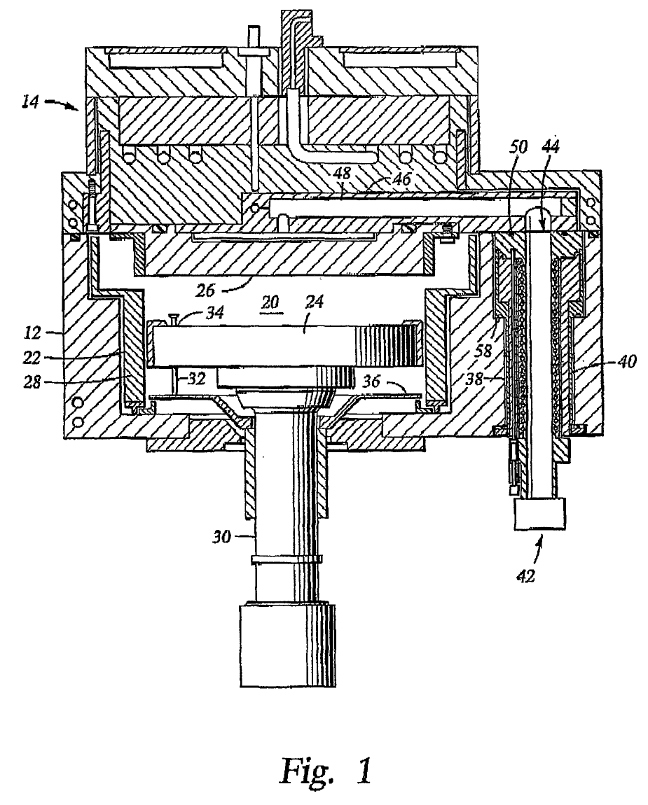

FIG. 1 is a cross sectional view of one embodiment of a chamber adapted to deposit a metal oxide, such as BST. A commercial available examplar chamber is available from Applied Materials, Inc. of Santa Clara, Calif. under the model name BST Gigacap™ Chamber. The chamber comprises a chamber body 12 supporting a heated lid assembly 14. The chamber body 12 defines an inner annular processing region 20 having a perimeter defined by an inner wall 22. A chamber liner 28 may be disposed adjacent the inner wall 22 of the chamber to provide a removable surface without the chamber which can easily cleaned and/or replaced. A substrate support member 24 extends through the bottom of the chamber and defines the lower end of the processing region 20. A gas distribution plate 26 mounted on the lid forms the upper limit of the processing region 20. The chamber body 12 and the lid assembly 14 may be made of a rigid material such as aluminum, stainless steel or combinations thereof. The chamber body 12 also defines a pumping port for purging the remains of the deposition vapor once it has been delivered over the substrate.

The substrate support member 24 may comprise a metal, such as aluminum, with a resistive heating element (not shown) attached thereto or embedded therein. In an alternative embodiment, the support member 24 may comprise a ceramic block and embedded ground plate which generates heat when subjected to RF energy emitted by an adjacent electrode. A suitable substrate support member and related lift assembly is shown and described in issued U.S. Pat. No. 6,120,609 entitled “Self Aligning Lift Mechanism,” filed on Jul. 14, 1997, and is incorporated herein by reference to the extent not inconsistent with the invention. An exemplar substrate support member is available from Applied Materials, Inc. of Santa Clara, Calif. under the model name CxZ Heater.

The substrate support member 24 generally is movable up and down on a central elevator 30 to move a substrate between a deposition position adjacent the gas distribution plate 26 and a substrate insertion/removal position below a slit valve formed through the chamber body 12. The entry point of the shaft 30 into the chamber is sealed with a collapsible bellows (not shown). The substrate may be lined from the substrate support member 24 and placed on a robot blade or lifted from the robot blade and placed on the substrate support member 24 by a set of lifting pins 32 slidably retained in a set of four passageways 34 extending through the substrate support member 24. Directly below each of the pins 32 is a lifting plate 36 which moves the pins 32 vertically within the chamber to allow a substrate to be lifted off or placed on a robot blade (not shown) which is moved into the chamber through the slit valve opening (not shown).

The chamber body 12 defines one or more passages 38 for receiving a heated gas delivery feedthrough 40 having an inlet 42 and an outlet 44 to deliver one or more precursor gases into the gas distribution plate 26 mounted on the lid assembly 14. The passage 38 defines an upper and a lower end of differing diameters to form a shoulder 58 where the upper and lower ends meet. The gas outlet 44 is fluidly connected to a mixing gas manifold 46 which includes at least a first gas passage 48 to deliver one or more gases into the gas distribution plate 26. An O-ring seal 50, preferably made of Teflon® polymer with a stainless steel c-spring, is located around the outlet 44 on the upper chamber wall to provide a sealing connection between the gas delivery feedthrough 40 and the gas manifold 46.

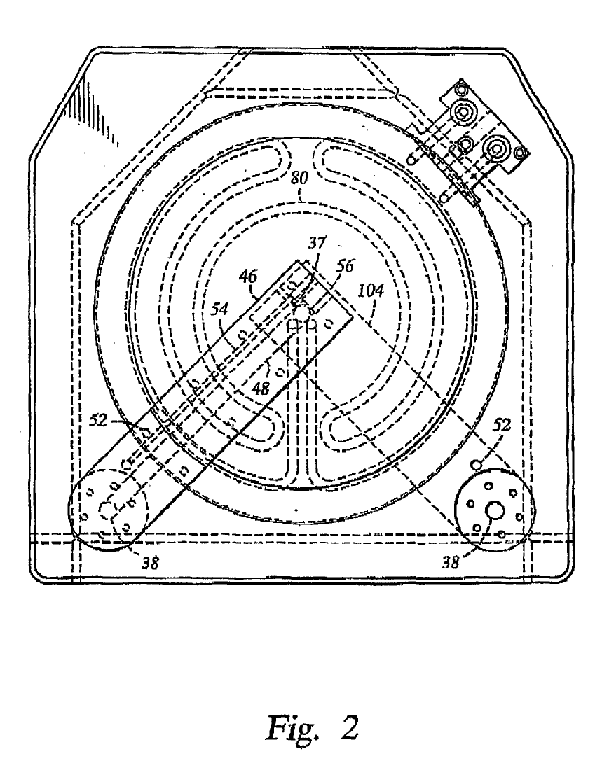

FIG. 2 is a top view of a lid assembly showing the mixing gas manifold in phantom. One or more oxidizer gas passages 52, similar to passage 38, are also formed in the chamber body 12 adjacent the passage 38 for receiving an oxidizer gas delivery feedthrough which can be heated if desired to deliver one or more oxidizer gases through the chamber wall to the mixing gas manifold 46. A gas passage 54 is formed in the mixing gas manifold 46 to deliver the oxidizer to a mixing point 56 located in the gas manifold adjacent the entry port into the gas distribution plate 26. A restrictive passage 37 connects the end of the oxidizer gas passage 54 to the end of the vaporized gas passage 48 to provide high velocity delivery a well as mixing of the gas mixture upstream from the gas distribution plate 26.

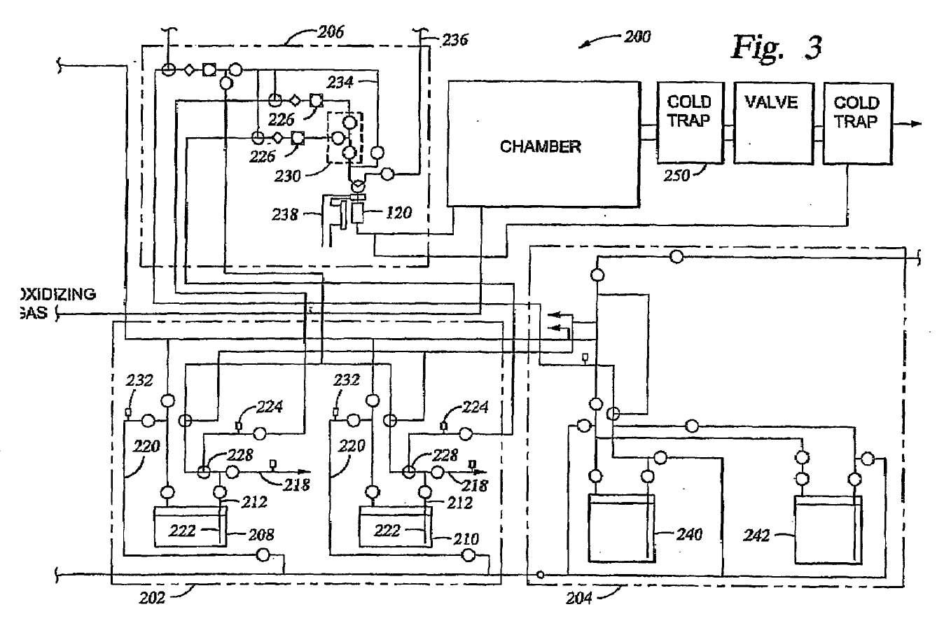

FIG. 3 is a schematic view showing a liquid delivery system 200 for the present metal oxide deposition chamber. The liquid delivery system generally includes a liquid precursor module 202, a solvent module 204, and a vaporizer module 206. In one embodiment, the liquid precursor module 202 includes two pressurized ampoules 208, 210 and a liquid delivery line 212 connected to each ampoule. Valves are disposed along the length of the liquid delivery lines to control flow of liquid from the ampoules to a mixing port and then into the vaporizer. In one embodiment, zero dead volume valves which are described below, are used to prevent collection of precursor therein which can compromise the valves as well as negatively affect process stabilization and/or repeatability. The zero dead volume valves enable rapid flushing of precursor from the lines using solvent. Solvent is supplied to the liquid delivery line 212 to flush the system during maintenance. Additionally, a purge gas line is connect to the liquid delivery line to rapidly purge solvent from the line so that the system, including the ampoules, valves and/or LFCs, can be prepared for maintenance in ten (10) to thirty (30) minutes. The valving is designed so that when necessary, solvent can be introduced into the liquid delivery line upstream from the mixing port to flush the line through a bypass line 218 and out through a recovery system which includes a cold trap and exhaust manifold.

The ampoules 208, 210 are designed to deliver the liquid precursors at high pressure, for example, up to 500 psi, without having to rely on high pressure pumps, and no high cycle mechanical pump with rubbing parts exposed to precursors. To provide the pressure, an inert gas such as argon is charged into the ampoules 208, 210 at a pressure of about 90 psi through line 220. A liquid outlet line 222 is disposed in each ampoule 208, 210 so that as the inert gas, e.g., argon, is delivered to the ampoule 208, 210 and the appropriate valves are opened, the liquid is forced out through the liquid outlet line 222 through a suitable valve and into the liquid delivery line 220.

The delivery line 212 is connected from each ampoule 208, 210 to the vaporizer 120. A first zero dead volume valve is disposed on the outlet of the ampoule to control delivery of the liquid to the delivery line 212. The valve is preferably a three-way valve connecting the bypass line 218 and the liquid delivery line 212. The bypass line 218 in turn is connected to a cold trap 250 and an exhaust manifold (not shown). A high pressure gauge 224 and a LFC 226 are disposed downstream from a valve 228 introducing the solvent and the purge gas. The LFC controls delivery of the liquid to the mixing port 230 connected between the liquid precursor delivery lines. A low pressure gauge 232 is disposed on the inert gas line 232 to monitor pressure.

The liquid precursor delivery lines 212 deliver liquid precursors into the mixing port 230 upstream from the vaporizer 120. A solvent delivery line 234 also delivers a solvent into the liquid delivery line 212 downstream from the mixing port 230 where the liquid precursors and the solvent are mixed and delivered into the vaporizer 120. At the vaporizer 120, a carrier gas line 236 delivers a carrier gas into the delivery line 212 to carry the liquid precursors and the solvent into the vaporizer 120 through the capillary tube or nozzle. In addition, a concentric carrier line 238 delivers a carrier gas around the nozzle or injection tip to ensure that even a small amount of liquid is delivered to the vaporizing surfaces. The delivery line from the mixing port 230 and into the vaporizer 120 is preferably made of a material having a low coefficient of friction, such as Teflon® polymer, which does not impede or inhibit the flow rate of the fluid. This feature assists in the delivery of small volumes of liquid precursor.

The solvent module 204 includes one or more chargeable ampoules similar to the liquid precursor ampoules. In one embodiment, there are two solvent ampoules 240, 242 and two liquid precursor ampoules 208, 210. The liquid precursor ampoules 240, 242 can deliver two separate precursors which can be mixed at the mixing port 230 or can deliver the same precursor together or alternatively.

The liquid precursor ampoules 240, 242 are designed with a slotted/sculptured bottom to draw the liquid downwardly in each ampoule 240, 242 so that the liquid may (1) be detected at very low levels and (2) be drawn out of each ampoule 240, 242 even at low levels. This is particularly important in dealing with expensive liquids which are preferably not wasted. In addition, the ampoules 240, 242 include an ultrasonic detector for discerning the volume of liquid in each ampoule 240, 242 even at low levels so that continuous processing may be achieved.

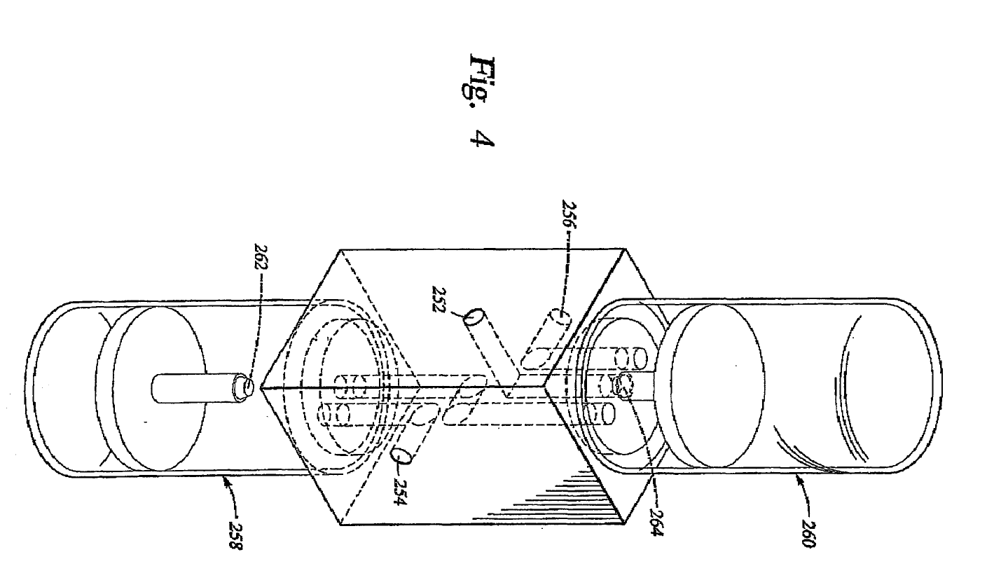

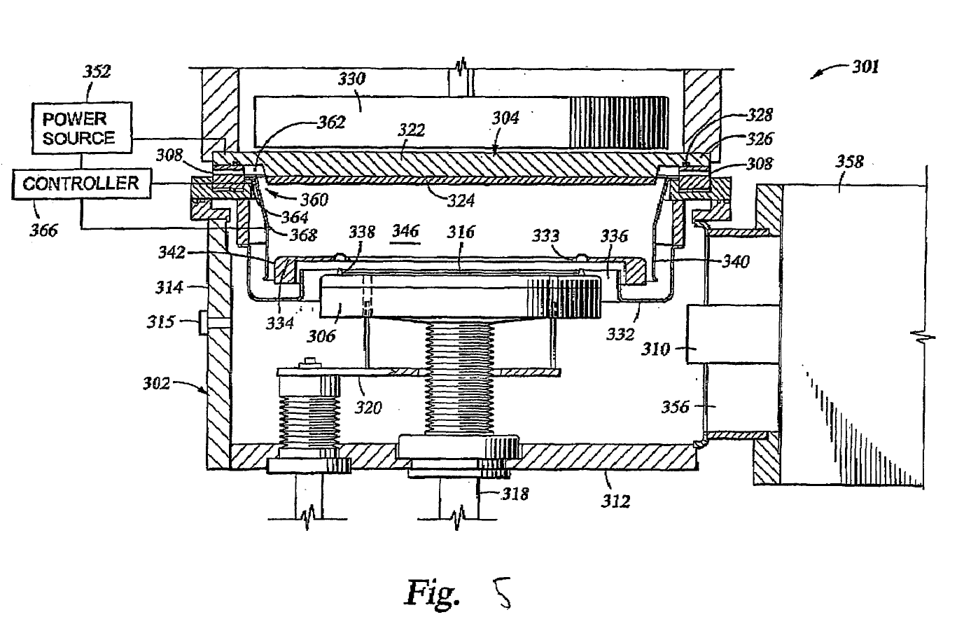

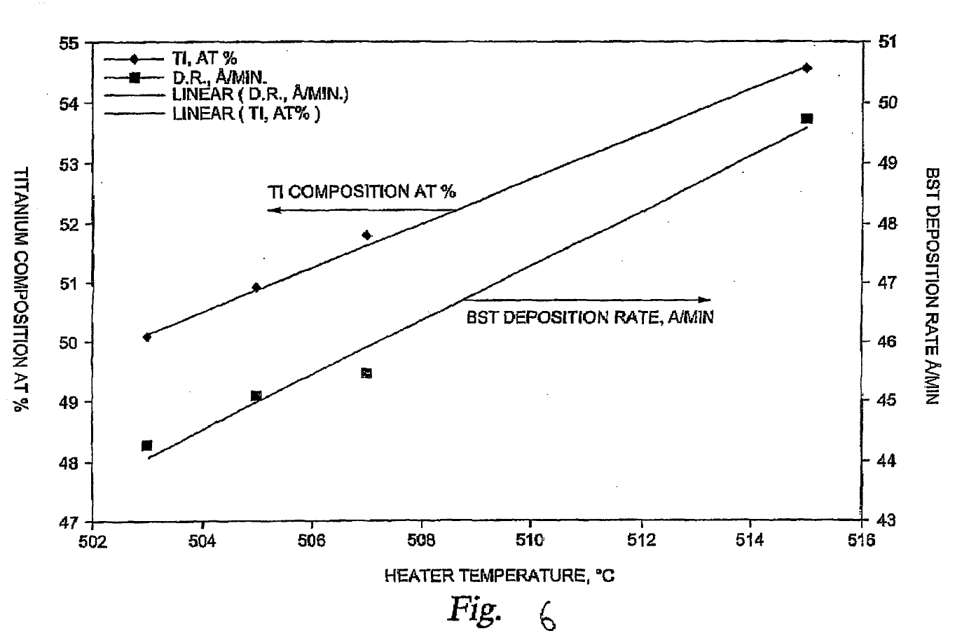

FIG. 4 is a perspective view of a zero dead volume valve. The valve includes a liquid precursor inlet 252 and a solvent inlet 254 and a single outlet 256. The solvent is routed through the solvent inlet 254 through a solvent control actuator 258 and into the liquid precursor control actuator 260. A plunger 262 controls entry of the solvent into and consequently out of the solvent control actuator 258 as shown in FIG. 5. The liquid precursor is routed through the precursor inlet 252 and into precursor control actuator 260 when the plunger 264 in the actuator is in the open position. When the plunger 262 is in the closed position, the precursor is prevented from entering the actuator and is flushed out of the valve by the plunger 262 and by flow of solvent through the valve. The solvent is able to enter the precursor control act 260 whether the plunger 262 is in the open or closed position to enable solvent purge of the valve as shown in FIG. 5. The plunger 262 is contoured to seal the liquid precursor inlet while enabling solvent flow into the actuator. Continuous solvent flow allows the system to be continuously purged with solvent when the liquid precursors are shut off.

Additionally, a single a valve is disposed on the outlets of the ampoules to control delivery of liquid precursor and to prevent clogging in the actuator. Also, the two way valves are preferably disposed on the downstream side of the liquid flow controller in the vaporizer panel.

The delivery tubes are preferably made of a material such as Teflon® polymer to promote frictionless fluid flow therein to prevent clogging and deposition along the path of the tubes. It has been learned that Teflon® polymer provides a better conduit for materials such as the barium, strontium and titanium precursor liquids used in the deposition of BST.

The plumbing system is designed to enable rapid flushing of the lines and valves during routine maintenance. Additionally, the system is adapted to enable sequential shutdown of each of the valves as well as to deliver an automatic flush of a controlled amount of solvent though the vaporizer 120 and the delivery lines in case of a power outage. This safety feature ensures that during uncontrolled power outages, the system will not be subject to clogging.

The delivery system may also comprise a bubbler system. A carrier gas such as argon can be bubbled through a solvent to suppress premature solvent evaporation from the precursor Thereby ensuring the precursor liquid will not be dried out en route to the vaporizer 120.

In situ liquid flow controllers and piezoelectric control valves are also used to maintain heightened control over the system. The high pressure gauges present on precursor and solvent lines as well as vacuum gauges on the vacuum manifolds are used to measure whether chemicals remain in the lines. These gauges are also used for on board leak integrity measurements.

One embodiment of the present invention includes a liquid CVD component delivery system. The system having two pressurized ampoules of liquid CVD component and a related LFC, such as a needle valve, which operates without sliding seals and can be used at pressures of less than 250 psi. Two solvent ampoules deliver solvent into the liquid delivery lines for cleaning and maintenance as well as into the mixing port during processing.

PVD Deposition Chamber

The electrodes of a capacitor may comprise a conductive material, such as platinum, ruthenium, ruthenium oxide, iridium, and or iridium oxide, which may be deposited by chemical vapor deposition (CVD) or physical vapor deposition (PVD). In one embodiment, the conductive material is deposited by PVD.

FIG. 5 is cross sectional view of a PVD chamber. One commercially available examplar chamber is the Endura chamber, available from Applied Materials, Inc. of Santa Clara, adapted for PVD deposition of conductive materials used in fabrication of semi-conductor devices. The PVD chamber 301 generally comprises a chamber enclosure 302, a target 304, a substrate support 306, a gas inlet 308 and a gas exhaust 310. The chamber enclosure 302 includes a chamber bottom 312 and a chamber side wall 314. A slit valve 315 is disposed on a chamber side wall 314 to facilitate transfer of a substrate 316 into and out of the PVD chamber 301. The substrate support 306 is disposed on a substrate support lift assembly 318 through the chamber bottom 312. Typically, a temperature control element (not shown), such as a heater, is incorporated within the substrate support 306 to control the temperature of the substrate 316 during processing. The substrate support 306 may be made of stainless steel, and the temperature control element comprises a platinum/rhodium heater coil. The substrate support lift assembly 318 moves the substrate support 306 vertically between a substrate transfer position and a substrate processing position. A lift pin assembly 320 lifts the substrate 316 off the substrate support 306 to facilitate transfer of the substrate 316 between the chamber and a robot blade (not shown) used to transfer the substrate 316 into and out of the chamber 301.

The target 304 is disposed in the top portion of the chamber enclosure 302. Preferably, the target 304 is positioned directly above the substrate support 306. The target 304 generally comprises a backing plate 322 supporting a plate 324 of sputturable material. Target materials used for forming conductive layers such as electrode layers can include platinum, ruthenium, iridium, as well as copper, titanium, aluminum and other metals. Target materials may also include combinations of these metals as well as other materials used for other PVD processes, such as reactive sputtering, wherein the sputtered material reacts with other materials or gases in the process cavity to form the deposited layer. The backing plate 322 includes a flange portion 326 that is secured to the chamber enclosure 302. A seal 328, such as an O-ring, may, be provided between the flange portion 326 of the backing plate 322 and the chamber enclosure 302 to establish and maintain a vacuum environment in the chamber during processing. A magnet assembly 330 is disposed above the backing plate 322 to provide magnetic field enhancement that attracts ions from the plasma toward the target sputtering surface to enhance sputtering of the target material.

A lower shield 332 is disposed in the chamber to shield the interior surfaces of the chamber enclosure 302 from deposition. The lower shield 332 extends from the upper portion of the chamber side wall 314 to a peripheral edge of the substrate support 306 in the processing position. A clamp ring 334 may be used and is removably disposed on an inner terminus 336 of the lower shield 332. When the substrate support 306 moves into the processing position, the inner terminus 336 surrounds the substrate support 306, and a peripheral portion 338 of the substrate 316 engages an inner terminus 333 of the clamp ring 334 and lifts the clamp ring 334 off the inner terminus 336 of the lower shield 332. The clamp ring 334 serves to clamp or hold the substrate 316 as well as shield the peripheral portion 338 of the substrate 316 during the deposition process. Alternatively, instead of a clamp ring 334, a shield cover ring (not shown) is disposed above an inner terminus of the lower shield 332. When the substrate support 306 moves into the processing position, the inner terminus of the clamp ring 334 positioned immediately above the peripheral portion of the substrate 316 to shield the peripheral portion of the substrate 316 from deposition.

An upper shield 340 may be disposed within an upper portion of the lower, shield 332 and extends from upper proportion of the chamber side wall 314 to a peripheral edge 342 of the clamp ring 334. The upper shield 340 may comprise a material that is similar to the materials that comprise the target 304. The upper shield 340 may be a floating-ground upper shield that provides an increased ionization of the plasma compared to a grounded upper shield. The increased ionization provides more ions to impact to target 304 leading to a greater deposition rate because of the increased sputtering from the target 304. Alternatively, the upper shield 340 can be grounded during the deposition process.

A gas inlet 308 disposed at the top portion of the chamber enclosure 302 between the target 304 and the upper shield 340 introduces a processing gas into a process cavity 346. The process cavity 346 is defined by the target 304, the substrate 316 disposed on the substrate support 306 in the processing position and the upper shield 340. Typically, argon is introduced through the gas inlet 308 as the process gas source for the plasma. A gas exhaust 310 is disposed on the chamber side wall 314 to evacuate the chamber prior to the deposition process, as well as control the chamber pressure during the deposition process. In one embodiment, the gas exhaust 310 includes an exhaust valve 356 and an exhaust pump 358. The exhaust valve 356 controls the conductance between the interior of the chamber 301 and the exhaust pump 358.

To supply a bias to the target 304, a power source 352 is electrically connected to the target 304. The power source 352 may include an RF generator and an RF matching network coupled to the target 304. The power source 352 supplies the energy to the process cavity to strike and maintain a plasma of the processing gas in the process cavity during the deposition process.

A gas exhaust 310 is disposed on the chamber side wall 314 to evacuate the chamber 301 prior to the deposition process, as well as control the chamber pressure during the deposition process. The gas exhaust 310 includes an exhaust valve 356 and an exhaust pump 358. The exhaust valve 356 controls the conductance between the interior of the chamber 301 and the exhaust pump 358. The exhaust pump 358 may comprise a turbomolecular pump in conjunction with a cryopump to minimize the pump down time of the chamber 301. Alternatively, the exhaust pump 358 comprises a low pressure, a high pressure pump or a combination of low pressure and high pressure pumps.

Other types of sputtering can be utilized for forming the electrodes of capacitors, such as an IMP-PVD processing an IMP Vectra™ chamber, available from Applied Materials, Inc. of Santa Clara, Calif. The IMP chamber additionally contains power supply coupled to the substrate to create a bias and a coil disposed between the target and the substrate, the coil being coupled to a third power supply. The coil is used to densify the plasma and the biased substrate to attract the sputtered particles in a substantially perpendicular direction to the substrate surface.

Metal Oxide Deposition

A low thermal budget CVD process for the deposition of a BST layer from vaporized precursors is set forth below. Further details of CVD deposition of a metal oxide layer, such as a BST layer, can be found in co-pending U.S. patent application, entitled “Low Temperature CVD BST Deposition,” filed on Jun. 29, 2000, is hereby incorporated by reference in its entirety not inconsistent with the present process. Other metal oxides which also may be used in the present process include, but is not limited to, tantalum pentoxide (Ta₂O₅), zirconate titanate (ZrxTiyOz), strontium titanate (SrTiO₃), lead zirconate titanate (PZT), lanthanum-doped PZT, bismuth titanate (Bi₄Ti₃O₁₂), barium titanate (BaTiO₃), or the like.

The BST process reacts the vaporized liquid precursors of the three components with an oxidizing gas such as oxygen, N₂O, O₃ or combinations thereof, at a temperature above the vaporization temperature of the precursors and below a temperature of less than or about 480° C. The temperature range of 480° C. is above the thermal decomposition temperature of the component precursors, and at a temperature wherein the deposition is said to be kinetically controlled, i.e., the rate of layer formation is limited by the reaction at the surface of the substrate. Under this temperature regime, the raw materials reaching the surface expand over a large area prior to decomposition, and form a more uniform and conformal layer having a smooth surface even when the surface of the underlying substrate comprises irregular features such as trenches or vias.

In one embodiment, the delivery lines which carry the component precursors from the vaporizer to the chamber are maintained at a temperature corresponding to the average of the preferred temperatures of the three component precursors in the mixture. The preferred temperature for each component precursor is within a window defined by condensation and decomposition temperatures of the component precursor. The precursor vapor composition for use in the deposition process is a mix of vaporized liquid precursors combined in predetermined mass or molar proportions. Both a single precursor source or two or more precursor sources can be used.

For use in deposition of BST, the first liquid precursor source may be a mixture of Ba and Sr polyamine compounds in a suitable solvent such as tetrahydrofuran (THF). Examples of barium precursors used in the method described herein include bis(tetra methyl heptanedionato) barium, commonly known as Ba (tmhd)₂, bis(tetra methyl heptanedionato) barium penta methyl diethylene triamine, commonly known as Ba PMDET (tmhd)₂, bis(tetra methyl heptanedionato) barium tetraglyme, commonly known as Ba (tmhd)₂, tetraglyme, and combinations thereof. Examples of strontium precursors used in the method described herein include bis(tetra methyl heptanedionato) strontium, commonly known as Sr (tmhd)₂, bis(tetra methyl heptanedionato) strontium penta methyl diethylene triamine, commonly known as Sr PMDET (tmhd)₂, bis(tetra methyl heptanedionato) strontium tetraglyme, commonly known as Sr (tmhd)₂ tetraglyme, and combinations thereof. Precursors, such as bis(tetra methyl heptanedionato) barium and bis(tetra methyl heptanedionato) strontium, without adducts, such as penta methyl diethylene triamine (PMDET) are preferably used in the deposition method described herein. In one embodiment, the mixtures include combining Ba(tmhd)₂ and Sr(tmhd)₂, combining Ba PMDET (tmhd)₂ and Sr PMDET (tmhd)₂, or in the alternative, Ba (tmhd)₂ tetraglyme and Sr (tmhd)₂ tetraglyme. A preferred molar ration between the barium and strontium precursors (Ba:Sr) is between about 1:1 and about 2:1.

The second liquid precursor source is a titanium precursor preferably bis(tetra methyl heptanedionato) bis isopropanide titanium, commonly known as Ti (I—Pr—O)(tmhd)₂, or other titanium metal organic sources, such as Ti(tBuO)₂(tmhd)₂, in a suitable solvent such as tetrahydrofuran (THF).

In one embodiment, a solution of precursors for the deposition of a BST layer comprises bis(tetra methyl heptanedionato) barium (Ba(tmhd)₂), bis(tetra methyl heptanedionato) strontium (Sr(tmhd)₂), and bis(tetra methyl heptanedionato) bis isopropanide titanium (Ti (I—Pr—O)(tmhd)₂). Varying the proportions of the mixed precursors provides certain flexibility in controlling the composition of the deposited BST layer. The molar ratio between the combined metals in the liquid precursors is preferably between about 1:1:38 (or about 2.5 mol %: about 2.5 mol %: about 95 mol %) and about 1:1:4.7 (or about 15 mol %: about 15 mol %: about 70 mol %) barium:strontium:titanium (Ba:Sr:Ti), The molar ratio may vary based upon the requirements of the layer composition and the restriction of the total solubility in the solvent. The barium, strontium, and titanium precursors are preferably vaporized utilizing an inert carrier gas, such as argon, having a flow rate to the chamber of between about 100 sccm and about 400 sccm, which is referred to as Ar-A herein.

The process may be sensitive to changes in the temperature of the substrate. It has been found that substrate temperature at or below about 480° C. result in the deposition of uniform layers having a controllable layer composition. In one embodiment, the conformal BST layer is deposited at a temperature of between about 470° C. and about 480° C. to provide a consistent layer composition at a commercially acceptable deposition rate. Additionally, the sensitivity of the deposition rate of the Ba, Sr, and Ti precursors to temperature is similar at temperatures at or below about 480° C. This property reduces the temperature sensitivity of the BST layer composition at or below about 480° C., and provides a more uniform deposition and increased composition consistency in the deposited material. Generally, because of the heat dissipation in the space between the heater and the substrate during the deposition of the BST layer, the heater may be maintained at a temperature between about 30° C. and about 100° C. higher than the desired substrate temperature.

It has been discovered that the process described herein allows deposition of BST layers having excellent physical properties by maintaining the pressure within the chamber between about 2 Torr and about 8 Torr to avoid gas phase reactions. In one embodiment, the chamber pressure is maintained between about 2 Torr and about 4 Torr during the deposition process. In another embodiment, a pressure of about 4 Torr has been used to avoid gas phase reactions. By avoiding gas phase reactions, enhanced control of the composition of the deposited layer can be achieved by increasing the amount of raw material reaching the surface of the substrate.

It has been observed that BST layers deposited utilizing the above described processing conditions, and further illustrated in the examples below, produce an oxide layer comprising a titanium molar fraction of between about 50 mol % and about 53 mol % at a temperature at or below about 480° C. and at a pressure of between about 2 Torr and about 8 Torr. The BST layer also comprises from between about 15 mol % and about 33 mol % barium and between about 15 mol % and about 33 mol % strontium. The BST layer has been observed to comprises about 24 mol % barium and about 24 mol % strontium, when the barium and strontium precursors have abut a 1:1 Ba:Sr molar ratio.

The chemical and physical properties of the deposited BST layer can also be controlled by selectively supplying one or more oxidizers or varying the flow rate of the oxidizers. While the process described herein is suitable for use with a wide variety OF oxidizers, such as O₂, N₂O and O₃, it has now been found that the process also allows for the deposition of BST layers having high capacitance when O₂ is used as the primary or sole oxidizer. The oxidizing gas flow rate is may be between about 300 sccm and about 3000 sccm.

The invention also provides a second carrier gas flow, preferably a second argon flow having a passageway concentric with the passageway of a primary gas flow carrying the precursors or solvent to the vaporizer. The secondary gas flow, referred to as argon B flow, allows reduction or total elimination of liquids in the gas flow downstream from the vaporizer by capturing liquid droplets that may condense at the edge of the passageway of the first carrier gas flow, referred to as argon A (Ar-A) flow upstream from the vaporizer. The secondary gas flow, preferably of argon, has a preferred flow rate of between about 200 sccm and about 1000 sccm, and is referenced as argon B (Ar-B) herein. The vaporized precursor is then directed to the CVD reactor for deposition of a BST layer. Stabilizing the vaporization of the precursors allows more efficient use of the precursors and reduces material deposition on the chamber components, thus minimizing the need for repeated servicing of the deposition reactor.

Another aspect of the invention provides a heater spacing from the substrate for depositing the BST layer. The heater spacing allows for establishing and maintaining a temperature at which the precursors can decompose to deposit the layer thereby influencing the deposition rate as a higher decomposition temperature, i.e. a closer heater spacing, promotes an increased rate of deposition. The heater spacing has a preferred spacing of equal to or less than about 18 millimeters (mm), which corresponds to a preferred spacing of equal to or less than about 700 thousands of an inch (mils), for depositing a BST layer from the respective precursors on a 200 mm substrate. In one embodiment, the heater spacing is between about 7 mm (about 300 mils) and about 18 mm (about 700 mils).

An example of a process regime for the deposition of a BST film provides a solution of Ba(tmhd)₂, Sr(tmhd)₂, and Ti (I—Pr—O)(tmhd)₂ precursos for the deposition of a BST layer in an argon carrier gas (Ar-A) at a flow rate of about 130 sccm with an oxidizing gas flow rate of oxygen or nitrous oxide of about 500 sccm, and a secondary gas of argon at a flow rate of about 230 sccm. The processing gases are introduced into a processing chamber maintained at a pressure of about 4 Torr and a substrate temperature between about 470° C. and about 480° C. The deposited BST layer comprises between about 50 mol % and about 53 mol % of titanium. The heater is spaced at about 14 mm. The above described processing regime deposits the layer at a rate between about 20 Å/min and about 100 Å/min. In one embodiment, the above described processing regime produced a deposition rate between about 40 Å/min and about 50 Å/min.

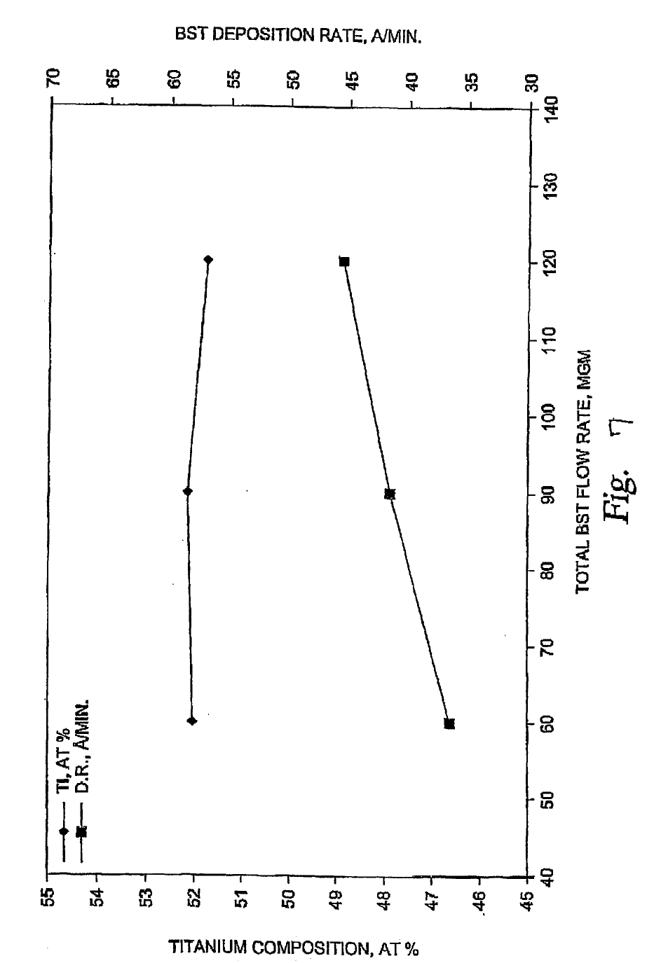

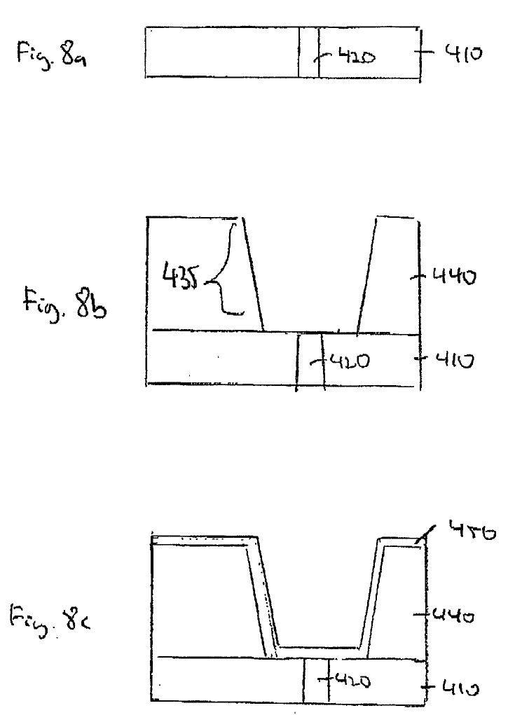

FIG. 7 is a graph of the deposition rate and titanium concentration of the deposited BST layer versus heater temperature in a 200 mm substrate process of one embodiment of the invention. An increase in heater temperature provides an increased deposition rate without substantial degradation of the precursors. An increase in heater temperature will also increase the titanium concentration (mol %) in the deposited layer. The heater temperature can vary from about 500° C. and about 510° C. to produce a titanium concentration of between about 50 mol % and about 53 mol % under the embodiment.

The first precursor was a mixture of Ba(tmhd)₂, Sr(tmdh)₂, and Ti (I-pr-o) (tmhd)₂ in THF solvent acetate which provides a molar ratio of Ba:Sr:Ti of about 1:1:8. A platinum layer was disposed on the substrate prior to being exposed to the precursors. A deposition rate of between about 45 Å/minute and about 48 Å/minute was achieved at a heater temperature of between about 500° C. and about 510° C., which gives a substrate temperature between about 470° C. and about 480° C., using a total liquid flow rate of the precursors of about 120 mg/m and a process gas flow rate of about 2000 sccm. A vaporizer according to the present invention was also used, wherein the vaporizer lines for the precursors were maintained at about 240° C.

As shown by FIG. 6, the deposition rate increases an average of about 0.45 Å/min for about 1° C. increase in the heater temperature at about 480° C., showing that the deposition rate has a strong sensitivity to temperature. The titanium concentration (mol %) in the deposited BST layer increases an average of about 0.36 Å/min for about each 1° C. increase in the heater temperature at about 480° C., showing that the titanium concentration has a strong sensitivity to temperature.

The BST film deposited with the above described deposition parameters can provide a high quality layer having good uniformity within the substrate and from substrate to substrate. A heater temperature between about 500° C. and about 510° C. provided a substrate temperature between about 470° C. and about 480° C. and a deposition rate of about 45 Å/minute.

FIG. 7 is a graph of the composition sensitivity of Ti and deposition rate to the total mass flow rate of the BST precursors in the CVD BST process described in FIG. 6. The concentration (mole %)) of Ti is plotted versus total BST flow rate in milligramns/minute (mgm). The Ti concentration of the deposited layer does not substantially change over the range of the BST flow rate. This property illustrates that the concentration of the layer is not sensitive to mass flow rates and therefore confirms that the deposition process is kinetically controlled and not controlled by gas phase reactions. Further, the deposition rate increases with total BST flow rate, therefore illustrating that the rate of layer formation is limited by the reaction of available materials at the surface of the substrate.

One exemplary process for CVD BST on a 200 mm substrate mounted on a heated substrate holder is described below. The deposition chamber is maintained at a pressure between about 2 Torr and about 8 Torr and preferably between about 2 Torr and about 4 Torr. The substrate is maintained at a temperature equal to or less than about 480° C., and preferably between about 470° C. and about 480° C. Vaporized liquid precursor comprising a solution of Ba(tmhd)₂, Sr(tmhd)₂, and Ti (I—Pr—O)(tmhd)₂, suspended in an inert carrier gas, preferably an argon gas (Ar-A), are introduced into the processing chamber at a flow rate of about 500 sccm, or between about 60 mg/m and about 120 mg/m. The Ba PMDET (tmhd)₂ and Sr PMDET (tmhd)₂ solution is formed by disposing the precursor in a liquid solvent, such as tetrahydrofuran (THF), at a molar ratio of Ba:Sr of between about 1:1 and about 2:1.

The argon carrier gas has a flow rate of between about 100 sccm and about 3000 sccm. In one embodiment, the argon carrier gas has a flow rate between about 400 sccm and about 800 sccm. An oxidizing gas, such as oxygen, having a flow rate between about 100 sccm and about 3000 is introduced into the processing chamber to react with the vaporized precursors to deposit the BST layer. An oxidizing gas flow rate between about 300 sccm and about 800 sccm is preferably used during the deposition process. A secondary carrier gas of argon is provided at a flow rate of between about 100 sccm and about 3000 sccm to ensure sufficient vaporization of the liquid precursor for efficient deposition of the BST layer. A secondary carrier gas of argon at a flow rate between about 400 sccm and about 800 sccm is preferably used. A spacing between the heater/showerhead and the substrate may be between about 7 mm (about 300 mils) and about 18 mm (about 700 mils). In one embodiment, the spacing between the heater/showerhead and the substrate is about 14 mm. The dielectric layer 622 may be deposited to a thickness between about 50 Å and about 500 Å. A dielectric layer thickness of less than 80 Å and prterably kess tan 50 Å brils totes crystalization during anneal.

Metal Oxide Anneal

The metal oxide layer, such as a BST layer, may be annealed to increase its dielectric constant which results in capacitors with improved capacitance and capacitance density. It is believe that annealing the BST layer increases the dielectric constant by increasing the crystallinity of the deposited HDC material. In one embodiment, the anneal process may be conducted in an inert gas such as nitrogen or argon. In another embodiment, the anneal is conducted in an oxidizing ambient. The BST layer is preferably annealed in a separate chamber, such as a RTP XEplus Centura® available from Applied Materials Inc., Santa Clara, Calif.

It is believed that the anneal temperature and the anneal time is limited by the temperature sensitive components of capacitor structures and of transistors which may be formed prior to the anneal. It has been determined that platinum electrodes are relatively stable at a temperature of 600° C. but may be degrade above 600° C. Although, the present process conducts an anneal of the BST layer at a temperature higher than 600° C. the duration of the anneal at a temperature of above 600° C. is short enough to prevent substantially damage or degradation of capacitor or transistor components.

In one embodiment, the anneal process comprises providing a first substrate temperature between about 600° C. and 900° C., maintaining the first substrate temperature for a time period of between about 0.1 seconds and 30 minutes, providing a second substrate temperature between about 500° C. to 600° C., and maintaining the second substrate temperature for a time period of at least 10 minutes. The anneal at a first substrate temperature is maintained for a short duration to form seed crystals in the BST layer without damaging capacitor or transistor components. The anneal at a second substrate temperature does not significantly damage capacitor or transistor components while still being at a high enough temperature to facilitate crystallization of the BST layer. In one embodiment, the first substrate temperature may be between 600° C. and 700° C. and may be maintained for a time period between about 10 seconds and about 10 minutes. In another embodiment, the first substrate temperature may be between about 700° C. and about 900° C. and may be maintained for a time period between about 0.1 seconds and about 1 minutes, preferably between about 0.1 seconds to about 5 seconds.

The higher the first temperature the lower the duration is necessary to form seed crystals. For instance, in general at a first temperature of 600° C., the first time period is between about 15 minutes to about 30 minutes. In general, at a first temperature of 700° C., the first time period is between about 5 seconds to 2 minutes. In general, at a first temperature of 800° C. the first time period is between about 0.2 seconds to 10 seconds. In general, at a first temperature of 900° C., the first time period is less than 0.1 seconds. For example, the second anneal may be conducted at a temperature of between about 500° C. to about 600° C, for at least 5 minutes. In one embodiment the first substrats temperature is provided to about 300° C. per sec. In pruthy by increasing the temperature at a rate between about 100° C. per sec to about 300° C. per sec. In another embodiment the second substrats temperature is provided by decreasing the temperature at a rate between about 50° C. per sec.

Electrode Deposition to about 150° C. per sec.

In one embodiment, an adhesion layer is deposited in the feature prior to the deposition of the bottom electrode. One example of an adhesion layer is a Ti, TiAIN, TiSiN, or TaSiN layer deposited by PVD. In one embodiment, the adhesion layer is deposited to a thickness of between about 10 Å to 50 Å. The adhesion layer may be subjected to partial oxidation through air exposure at room temperature. The adhesion layer can be used as the bottom contact plug preventing interlayer diffusion from the conductive material of the bottom electrode and the polysilicon material of the transistor.

The electrodes of the present process may comprises platinum, ruthenium, ruthenium oxide, iridium, and/or iridium oxide. Preferably, the electrode material is deposited by PVD. In one embodiment, the electrodes comprise platinum and the dielectric material between the electrode comprises BST. In another embodiment, the electrode material comprises iridium or iridium oxide and the dielectric material between the electrodes comprises lead zirconate titanate. In another embodiment, the bottom electrode material comprises iridium, the top electrode material comprises iridium oxide, and the dielectric between the electrode comprises PZT.

An exemplary processing regime for sputter depositing the platinum material comprises introducing an inert gas, such as argon or helium, into a processing chamber at a rate sufficient to produce a chamber pressure between about 2 mTorr and about 25 mTorr. The power supply 352 provides a power level between about 500 W and about 1000 W to sputter a 13 in diameter platinum target. The ions bombard the relatively negative biased target 304 and dislodge particles of platinum from the target 304. Some of the sputtered particles are directed toward the substrate 316 and are deposited thereon. The substrate 316 is maintained at a temperature between about 300° C. and about 500° C. The chamber is operated with low background water vapor, hydrogen, or oxygen to promote surface migration of the deposited electrode material. In one embodiment, platinum is deposited on the substrate to a thickness of between about 50 Å and about 500 Å for a 0.15 μm feature having an aspect ratio greater than 2:1, and preferably greater than 4:1.

In one embodiment the bottom electrode is stabilized according to the methods developed by the Matsushita Electric Company. The bottom electrode is annealed in a hydrogen reducing ambient, such as hydrogen or downstream plasma ammonia (NH₃) at a temperature of between about 400° C. to 500° C. A subsequent oxidizing anneal at a temperature of between 400° C. to 500° C. for a time period of about 5 to 60 min. A subsequent oxidizing anneal aat a temperature of between 400° C. to 500° C. for a time period of about 5 to 60 min. An oxidizing anneal is performed in order to stimulate the oxidizing ambient of the oxidizing ambient of the CVD deposition of the metal oxide material, such as BST. Electron scanning microscope photographs show that prior methods of performing an oxidizing anneals without a hydrogen anneal was found to produce defects in the bottom electrode by causing agglomeration of the thin electrode material. For example, a platinum bottom electrode in a 0.15 μm cup-type capacitor annealed in a 5% oxygen ambient at a temperature of 500° C. was found to agglomerate and to have defects. A platinum bottom electrode in a 0.15 μm cup-type capacitor first annealed in a hydrogen ambient at a temperature between about 400° C. and 500° C. and then anneal in a 5% oxygen ambient at a temperature of 500° C. was found to have good conformal coverage. It is believed that the hydrogen provides a bottom electron with a stable morphology for subsequent oxidizing anneal. The following setence relates to electrode stabilization and are invorporated herein in their entirely: Japan: 1999-155043; Japan:2000-265284.

Capacitor Fabrication

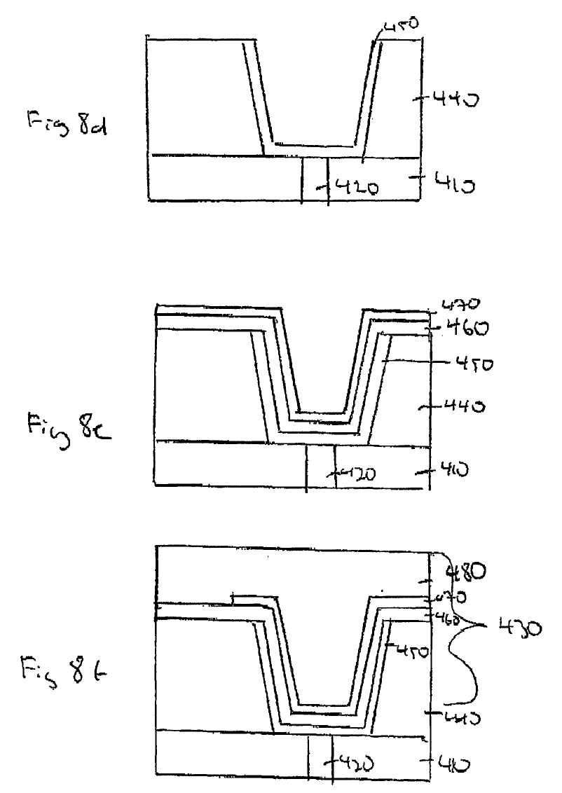

FIGS. 8a-f are schematic cross sectional views of one embodiment of fabricating a capacitor having a 3-D cup type structure. FIG. 8a shows a silicon substrate 410 having a contact 420 to a transistor (not shown). Depending on the particular process chemistry and desired end product, other substrate materials may be used, including other semiconductors, such as GaAs, InP, Si/Ge, SiC, and ceramics. Then, as shown in FIG. 8b, a dielectric material 440, such as silicon dioxide, is deposited over the substrate 410, patterned, and etched to form a feature 435. Then, as shown in FIG. 8c, a bottom electrode 450 such as a platinum bottom electrode is deposited over the feature 435. Then, as shown in FIG. 8d, the bottom electrode 450 is patterned by such methods as plasma etching or chemical mechanical polishing. Then, as shown in FIG. 8e, a dielectric material 460 such as BST is deposited over the bottom electron 450 at a temperature less than or equal to about 480° C. A top electrode 470 such as a platinum top electron is deposited over the dielectric material 460. Preferably, the second electrode 470 comprises the same material as the first electrode 450. Then, as shown in FIG. 8f, the top electrode 470 is etched and a dielectric material 430 is deposited over the top electrode 470 to form a capacitor 430. The substrate may then be further processed, such as planarization and/or further deposition of materials such as dielectric materials and conductive materials for subsequent metallization.

In one embodiment, delineation of the bottom electron 450 through chemical mechanical polishing of the platinum bottom electrode is preferred to circumvent problems with dry pt etching electrodes. Electron scanning microscope photographs confirms that platinum bottom electrodes may be delineated by CMP etch back. In another embodiment, the bottom electrode 450 is hydrogen annealed prior to deposition of the dielectric material 460 as described above in section describing electrode deposition.

In another embodiment, the dielectric material 460 is annealed prior to the deposition of the top electrode 470 as described above in the section describing the metal oxide anneal. In still another embodiment, the dielectric material 460 is annealed subsequent to the deposition of the top electrode 470 as described above in the section describing the metal oxide anneal. It is believed that the anneal of the dielectric material 460 and the top electrode 470 provides an improved interface and adhesion between the dielectric material 460 and the top electrode. The improved interface and adhesion provide improved electrical properties including improved capacitance and capacitance density of the layers. In another embodiment, the dielectric material 460 and the top electrode 470 may be annealed in an oxidizing ambient. The anneal in an oxidizing ambient diffuses oxygen to oxygen vacancy sites in the metal oxide layer used as the dielectric layer 460 which may develop during the deposition of the top electrode 470 or during inert gas annealing.

The properties of BST capacitors fabricated using a low temperature CVD deposition of BST at a temperature equal to or lower than 480° C. and a low thermal budget annealing process to provides was compared on 3-D and planar structures. The BST CVD precursors of Ba(THD)₂, Sr(THD)₂, Ti(THD)₂(O-i-Pr)₂ were thermally reacted with oxygen, in a commercially available CVD BST reactor. The platinum top electrode was defined by shadow mask/sputtering at room temperature, followed by anneals before and after top electrode deposition. The planar capacitors comprising a 300 Å BST film on a 200 mm wafer showed a leakage current density at +1V measured under slow ramp rate for a 1.0 sec. hold time of approximately 1×10⁻⁸ A/cm² except some wafer edge locations which had higher current leakage density. Capacitance density was in the range of 60 fF/μm² (t_{effox}=6 Å) after 700° C. annealing.

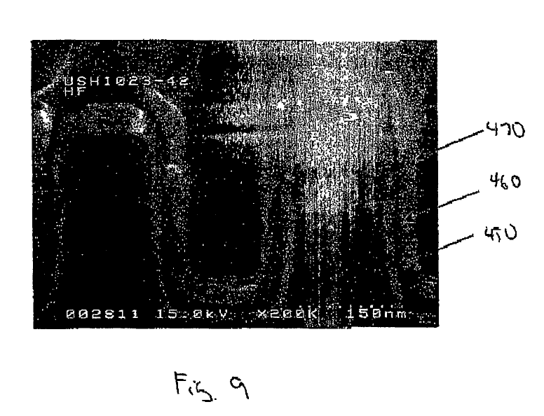

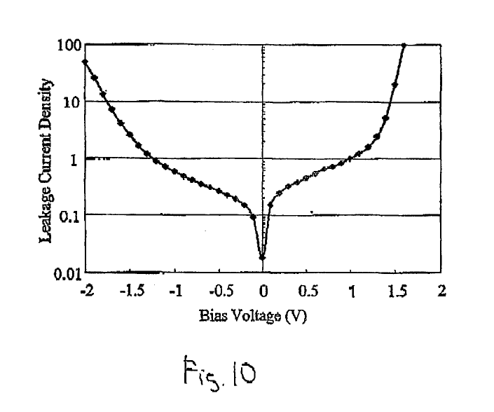

FIG. 9 an electron scanning microscope photograph of a 3-D cup structure cross-section (without step CMP/etchback). To investigate the performance of low temperature BST film on 3-D topography, platinum was sputtered on pattern wafers having 0.15 μm by 0.45 μm holes with a 0.3 μm depth. The platinum bottom electrode 450, the BST layer 460, and the platinum top electrode 470 can be seen. The low temperature BST film shows a high degree of conformity with no observable thickness change in the 3-D structure. Therefore, the present process demonstrates the formation of embedded BST capacitors in the magnitude of 0.1 μm geometry and having an aspect ratio 2 to 1 or greater, and even have an aspect ratio of 4 to 1 or greater. For the electrical properties the BST film on 3-D patterns, the IV curve is shown in FIG. 10. The leakage density at +1 V is as low as 1fA/cell averaged over a 256 k equivalent area, achieving the required level with by an approximately 10 times margin. Capacitance density of 28fF/μm² (t_{effox}=13 Å) or 12 fF/cell was achieved after annealing at less than 480° C. The capacitance density on the 3-D structure highlights is two times lower than the planar shadow mask device even though the CVD BST process conditions were the same. Low leakage current meeting the specification of <10fA/cell at 1V suggests there is margin for improving capacitance density to approximately 12fF/cell by trading off leakage current, e.g., by decreasing the thickness of the BST layer, increasing annealing temperature, or improving 3-D property control of the BST.

To achieve the low thermal budget capacitor processes with low stack height, BST (Barium Strontium Titanate) capacitor processes and structures have been studied. In previous work, it was necessary to employ relatively high temperature annealing to obtain the required BST capacitance density and charge leakage. However, on 3-D structures, high temperature anneals tend to destabilize the platinum electrodes which offer the advantage of high quality interfaces. Therefore, the present process provides for depositing conformal, smooth BST layers having a consistent composition and a high degree of crystallinity. Furthermore, the present process provides for fabricating a cup style BST cup capacitor having higher capacitance and reduced leakage current.

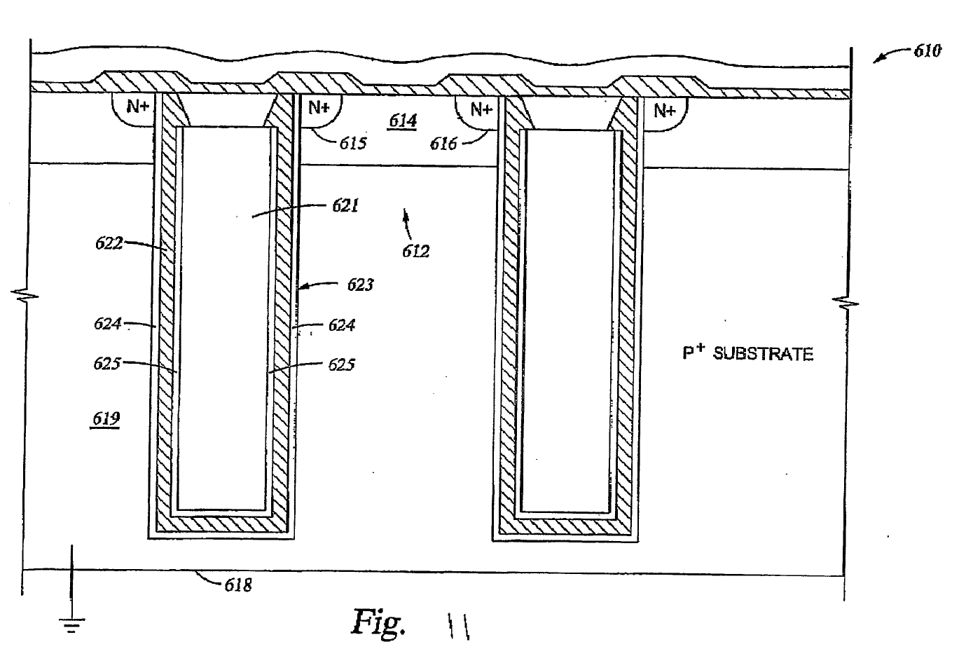

The inventors contemplate application of the trench capacitor according to the invention in a variety of DRAM designs in addition to the DRAM design shown for illustrative purposes in FIG. 11. FIG. 11 is a cross sectional view of another embodiment of a DRAM device having a trench capacitor formed using the methods of the invention. The DRAM device 610 is formed on a silicon substrate and generally comprises an access transistor 612 and a trench capacitor 618. The access transistor 612 for the DRAM device 610 is positioned adjacent a top portion of the trench capacitor 618. Preferably, the access transistor 612 comprises an NMOS transistor having a source region 615, a gate region 614 and a drain region 616. The gate region 614 comprises a P− doped silicon layer disposed over the P+ substrate. The source region 615 of the access transistor 612 comprises an N+ doped material disposed an a first side of the region 614, and the drain region 616 comprises an N+ doped material disposed on a second side of the region 614, opposite the source region 615. The source region 615 is connected to an electrode of the trench capacitor. The trench capacitor 618 generally comprises a first electrode, a second electrode and a dielectric material disposed therebetween. The Nt poles generally serves as a contact to the first electrode of the eupetype capacitor 618 and is connected to a ground connection. A trench 623 is formed in the P+ substrate 619 and filled with a heavily doped N+ polysilicon 621 which serves as the second electrode of the trench capacitor 618. The dielectric material 622 is disposed between the P+ substrate 619 and the N+ polysilicon 621. Conductive materials may be deposited inside the trench 623 between the P+ substrate 619 and the N+ polysilicon 621, encapsulating the dielectric material 622, to form the first and second electrodes of the DRAM structure. The conductive materials are generally deposited as first and second electrodes 624, 625.

The present process may be performed on chambers combined onto a single vacuum load locked substrate distribution apparatus to minimize wafer cycle time. Alternatively, a multiplicity of load locked substrate handling apparatuses may be employed depending on the need for redundant chambers and throughput balancing for the process flow through a given semiconductor device fabrication facility.

While the foregoing is directed to a referred embodiment of the invention, other and further embodiments of the invention may be devised without departing from the basic scope thereof, and the scope thereof is determined by the claims which follow.

This opproach has the advastage of esposing the capacitor to a high temperature anneal for crystalization but posed a challege for acheving electrode stability. To further improve thermal stability of the Pt, adding 5-10% Ir is beneficial.

1. A method of depositing a metal oxide layer on a substrate, comprising;
depositing a CVD metal oxide layer on the substrate at a substrate temperature of less than or equal to about 480° C.; and
annealing the metal oxide layer, wherein annealing comprises:
providing a first substrate temperature between about 600° C. and 900° C.;
maintaining the first substrate temperature for a time period of between about 0.1 seconds and 30 minutes;
providing a second substrate temperature between about 500° C. to 600° C.; and
maintaining the second substrate temperature for a time period of at least 15 minutes.

2. The method of claim 1, wherein the first substrate temperature is between about 600° C. and about 700° C. and is maintained for a time period between about 10 seconds and about 10 minutes.

3. The method of claim 1, wherein the first substrate temperature is between about 700° C. and about 900° C. and is maintained for a time period between about 0.1 seconds and about 1 minute.

4. The method of claim 3, wherein the first substrate temperature is between about 700° C. and about 900° C. and is maintained for a time period between about 0.1 seconds and about 5 seconds.

5. The method of claim 1, wherein providing a first substrate temperature comprises increasing the substrate temperature at a rate of between about 100° C./sec to about 300° C./sec.

6. The method of claim 1, wherein providing a second substrate temperature comprises decreasing the substrate temperature at a rate of between about 50° C./sec to about 150° C./sec.

7. The method of claim 1, wherein the CVD metal oxide layer has a thickness of about 80 Å or less.

8. The method of claim 7, wherein the CVD metal oxide layer has a thickness of about 50 Å or less.

9. The method of claim 1, wherein the metal oxide is barium strontium titanate.

10. The method of claim 1, wherein the metal oxide is lead zirconate titanate.

11. The method of claim 1, wherein the metal oxide is a high dielectric constant material selected from the group consisting of barium strontium titanate, lead zirconate titanate, tantalum pentoxide, zirconate titanate, strontium titanate, lanthium-doped lead zirconate titanate, bismuth titanate, and barium titanate.

12. The method of claim 1, wherein annealing the metal oxide layer is conducted in an oxidizing ambient.

13. A method for processing a substrate, comprising:
depositing a first electrode;
depositing a CVD metal oxide layer over the first electrode at a substrate temperature of less than or equal to about 480° C.;
annealing the metal oxide layer, wherein annealing comprises:
providing a first substrate temperature between about 600° C. and 900° C.;
maintaining the first substrate temperature for a time period of between about 0.1 seconds and 30 minutes;
providing a second substrate temperature between about 500° C. to 600° C.; and
maintaining the second substrate temperature for a time period of at least 10 minutes; and
depositing a second electrode over the oxide layer.

14. The method of claim 13, wherein the first substrate temperature is between about 600° C. and about 700° C. and is maintained for a time period between about 10 seconds and about 10 minutes.

15. The method of claim 13, wherein the first substrate temperature is between about 700° C. and about 900° C. and is maintained for a time period between about 0.1 seconds and about 1 minute.

16. The method of claim 15, wherein the first substrate temperature is between about 700° C. and about 900° C. and is maintained for a time period between 0.1 seconds and about 5 seconds.

17. The method of claim 13, wherein providing a first substrate temperature comprises increasing the substrate temperature at a rate of between about 100° C./sec to about 300° C./sec.

18. The method of claim 13, wherein providing a second substrate temperature comprises decreasing the substrate temperature at a rate of between about 50° C./sec to about 100° C./sec.

19. The method of claim 13, wherein the CVD metal oxide layer has a thickness of about 80 Å or less.

20. The method of claim 19, wherein the CVD metal oxide layer has a thickness of about 50 Å or less.

21. The method of claim 13, wherein the metal oxide is barium strontium titanate.

22. The method of claim 13, wherein the metal oxide is lead zirconate titanate.

23. The method of claim 13, wherein the metal oxide is a high dielectric constant material selected from the group consisting of barium strontium titanate, lead zirconate titanate, tanathium pentoxide, zirconate titanate, strontium titanate, lead zirconate titante, lanthanum-doped lead zirconate titanate, bismuth titanate, and barium titanate.

24. The method of claim 13, wherein the first electrode comprises a material selected from the group of platinum, ruthenium, ruthenium oxide, iridium, iridium oxide, and combinations thereof.

25. The method of claim 21, wherein the first electrode comprises platinum deposited by physical vapor disposition.

26. The method of claim 22, wherein the first electrode comprises a material selected from the group consisting of iridium and iridium oxide, the material being deposited by physical vapor deposition.

27. The method of claim 13, wherein the second electrode comprises a material selected from the group of platinum, ruthenium, ruthenium oxide, iridium, iridium oxide, and combinations thereof.

28. The method of claim 21, wherein the second electrode comprises platinum deposited by physical vapor deposition.

29. The method of claim 22, wherein the second electrode comprises a material selected from the group consisting of iridium and iridium oxide, the material being deposited by physical vapor deposition.

30. The method of claim 13, wherein annealing the metal oxide layer is conducted in an oxidizing ambient.

31. The method of claim 13, further comprising annealing the first electrode in a reducing ambient at a temperature between about 400° C. to about 500° C.

32. The method of claim 31, further comprising annealing the first electrode in a oxidizing ambient at a temperature of between about 400° C. to about 600° C.

33. The method of claim 13, further comprising delineating the bottom electron by chemical mechanical polishing.

34. The method of claim 13, wherein the first electrode is deposited over feature having sub 0.1 μm geometry.

35. A method for processing a substrate, comprising:
depositing a first electrode;
depositing a CVD metal oxide layer over the first electrode at a substrate temperature of less than or equal to about 480° C.; and
depositing a second electrode over the oxide layer; and
annealing the metal oxide layer and the second electrode, wherein annealing comprises:
providing a first substrate temperature between about 600° C. and 900° C.;
maintaining the first substrate temperature for a time period of between about 0.1 seconds and 30 minutes;
providing a second substrate temperature between about 500° C. to 600° C.; and
maintaining the second substrate temperature for a time period of at least 10 minutes.

36. The method of claim 35, wherein the first substrate temperature is between about 600° C. and about 700° C. and is maintained for a time period between about 10 seconds and about 10 minutes.

37. The method of claim 35, wherein the first substrate temperature is between about 700° C. and about 900° C. and is maintained for a time period between about 0.1 seconds and about 5 minutes.

38. The method of claim 37, wherein the first substrate temperature is between about 700° C. and about 900° C. and is maintained for a time period between about 0.1 seconds and about 5 seconds.

39. The method of claim 35, wherein providing a first substrate temperature comprises increasing the substrate temperature at a rate of between about 100° C./sec to about 300° C./sec.

40. The method of claim 35, wherein providing a second substrate temperature comprises decreasing the substrate temperature at a rate of between about 50° C./sec to about 120° C./sec.

41. The method of claim 35, wherein the CVD metal oxide layer has a thickness of about 80 Å or less.

42. The method of claim 41, wherein the CVD metal oxide layer has a thickness of about 50 Å or less.

43. The method of claim 35, wherein the metal oxide is barium strontium titanate.

44. The method of claim 35, wherein the metal oxide is lead zirconate titanate.

45. The method of claim 35, wherein the metal oxide is a high dielectric constant material selected from the group consisting of barium strontium titanate, lead zirconate titanate, tantalum pentoxide, zirconate titanate, strontium titanate, lead zirconate titante, lanthanum-doped lead zirconate titante, bismuth titanate, and barium titanate.

46. The method of claim 35, wherein the first electrode comprises a material selected from the group of platinum, ruthenium, ruthenium oxide, iridium, iridium oxide, and combinations thereof.

47. The method of claim 43, wherein the first electrode comprises platinum deposited by physical vapor deposition.

48. The method of claim 44, wherein the first electrode comprises a material selected from the group consisting of iridium and iridium oxide, the material being deposited by physical vapor deposition.

49. The method of claim 35, wherein the second electrode comprises a material selected from the group of platinum, ruthenium, ruthenium oxide, iridium, iridium oxide, and combinations thereof.

50. The method of claim 43, wherein the second electrode comprises platinum deposited by physical vapor deposition.

51. The method of claim 44, wherein the second electrode comprises a material selected from the group consisting of iridium and iridium oxide, the material being deposited by physical vapor deposition.

52. The method of claim 35, wherein annealing the metal oxide layer is conducted in an oxidizing ambient.

53. The method of claim 35, further comprising annealing the first electrode in a reducing ambient at a temperature between about 400° C. to about 500° C.

54. The method of claim 53, further comprising annealing the first electrode in a oxidizing ambient at a temperature of between about 400° C. to about 600° C.

55. The method of claim 35, further comprising delineating the bottom electron by chemical mechanical polishing.

56. The method of claim 35, wherein the first electrode is deposited over feature having sub 0.1 μm geometry.

57. A capacitor comprising:
a platinum bottom electrode;
a BST dielectric layer; and
a platinum top electrode, in which the capacitor has a current leakage of less than 10 fA/cell or less.

58. The capacitor of claim 57, wherein the capacitor is 3-D cup-type capacitor.

59. The capacitor of claim 57, wherein the capacitor has 0.1 μm geometry.

60. The capacitor of claim 59, wherein the capacitor has an aspect ratio of 2 to 1 or greater.

61. The capacitor of claim 60, wherein the capacitor has an aspect ratio of 4 to 1 or greater.

62. The capacitor of claim 57, wherein the BST dielectric layer has a thickness of about 80 Å or less.

63. The capacitor of claim 62, wherein the BST dielectric layer has a thickness of about 50 Å or less.

64. A method of depositing a metal oxide layer on a substrate, comprising:
depositing a CVD metal oxide layer on the substrate at a substrate temperature of less than or equal to about 480° C.; and
annealing the metal oxide layer, wherein annealing comprises:
providing a first substrate temperature between about 500° C. and 900° C.;
maintaining the first substrate temperature for a time period of between about 0.1 seconds and 30 minutes; and
providing a second substrate temperature between about 500° C. to 750° C.
